(19) United States
(12) Patent Application Publication
(10) Pub. No.: US 2016/0268488 A1
(43) Pub. Date: Sep. 15, 2016

(54) WAVELENGTH CONVERSION ELEMENT, METHOD OF MAKING, AND LIGHT-EMITTING SEMICONDUCTOR COMPONENT HAVING SAME

(71) Applicant: OSRAM OPTO SEMICONDUCTORS GMBH, Regensburg (DE)

(72) Inventors: Britta Goeoetz, Regensburg (DE); Alan Piquette, Peabody, MA (US); Christopher A. Tarry, Portsmouth, NH (US)

(21) Appl. No.: 15/033,165

(22) PCT Filed: Oct. 28, 2014
(86) PCT No.: PCT/EP2014/073104

§ 371 Date: Apr. 29, 2016

Related U.S. Application Data
(60) Provisional application No. 61/896,888, filed on Oct. 29, 2013.

(51) Int. Cl. H01L 33/50; H01L 33/08; H01L 33/02; H01L 33/60; H01L 33/32

(52) U.S. Cl. CPC H01L 33/505; H01L 33/60; H01L 33/502; H01L 33/32; H01L 33/02; H01L 33/08; H01L 2933/0041; H01L 2933/0058

(57) ABSTRACT

In various embodiments, a wavelength conversion element is provided. The wavelength conversion element includes a ceramic grid material, which forms a grid having a plurality of openings, which are surrounded by the grid material in a main extension plane of the grid and reach through the grid in a direction perpendicular to the main extension plane of the grid, wherein the openings are filled with conversion segments.

### RELATED APPLICATIONS

The present application is a national stage entry according to 35 U.S.C. §371 of PCT application No.: PCT/EP2014/073104 filed on Oct. 28, 2014, which claims priority to U.S. provisional application No.: 61/896,888, filed on Oct. 29, 2013, and is incorporated herein by reference in its entirety.

### TECHNICAL FIELD

A wavelength conversion element and a method for producing a wavelength conversion element are specified. A light-emitting semiconductor component including a wavelength conversion element and a method for producing a light-emitting semiconductor component including a wavelength conversion element are furthermore specified.

Certain embodiments specify a wavelength conversion element for a light-emitting semiconductor component. Further embodiments specify a method for producing a wavelength conversion element. Further embodiments specify a light-emitting semiconductor component including a wavelength conversion element and a method for producing such a light-emitting semiconductor component.

### SUMMARY

In accordance with at least one embodiment, a wavelength conversion element includes a grid having a plurality of openings. The grid can be formed in particular by a ceramic grid material. The grid has a main extension plane. That means that the grid has a larger dimensioning in directions along the main extension plane than in a direction perpendicular to the main extension plane, which corresponds to the thickness of the grid. The openings in the grid are surrounded by the grid material in the main extension plane of the grid and reach through the grid in a direction perpendicular to the main extension plane. Furthermore, the wavelength conversion element has conversion segments in the openings, wherein the openings can preferably be filled with the conversion segments. That can mean, in particular, that the conversion segments completely fill the openings at least in a plane parallel to the main extension plane of the grid, such that no gaps are present between the grid material and the conversion segments. Furthermore, the conversion segments can also have a thickness corresponding to the thickness of the grid, such that the openings can be completely filled with the conversion segments. As an alternative thereto, it is also possible for the grid to have a thickness which is greater than a thickness of the conversion segments, such that the conversion segments do not completely fill the openings in a direction perpendicular to the main extension plane of the grid. The grid can also be denoted as a separator or separation grid including a separator material which separates the conversion segments.

The conversion segments can preferably be designed in a laminar fashion, such that each of the conversion segments has a main extension plane. Perpendicular to the main extension plane, each of the conversion segments has a thickness. The main extension plane of the conversion segments and the main extension plane of the grid are preferably parallel to one another.

In accordance with at least one further embodiment, a method for producing a wavelength conversion element includes a step A, in which a layer composed of an unsintered ceramic grid material is produced.

Here and hereinafter, a layer composed of a ceramic material should be understood to mean a layer which for the most part includes a ceramic material. In this case, “for the most part” means that the ceramic material takes up a proportion by weight of more than 50%, in particular of more than 75% and preferably of more than 90%, of the weight of the layer composed of the ceramic material. Furthermore, a layer composed of a ceramic material can also substantially consist or consist of the ceramic material. A ceramic material should be understood to mean here, in particular, an oxide-containing material or a nitride-containing material, wherein here and hereinafter materials having only a short-range order and no long-range order also come under the term “ceramic material”. Accordingly, inorganic glasses are also included by the wording “ceramic material”.

In order to produce the layer composed of the unsintered ceramic grid material, it is possible, for example, to produce a slurry or a paste including the ceramic grid material. By means of a suitable casting method, it is possible to produce a green body in the form of a green sheet or layer, for example in the form of a plate or a tape, from the slurry or paste. In this case, it can also be possible that a plurality of green sheets or layers produced in this way are laminated onto one another in order to achieve a desired thickness of the green body and thus of the grid. In particular, a plurality of green layers composed of the unsintered ceramic grid material can thus also be applied one on top of another in order to form the grid, such that the layer composed of the unsintered ceramic grid material that is produced in method step A can also be formed from a plurality of such layers. The grid can correspondingly include one or a plurality of layers of the grid material, which are sintered together in the completed state of the wavelength conversion element. The embodiments described here and hereinafter therefore relate both to methods in which only one layer composed of an unsintered ceramic grid material is produced and to methods in which a plurality of layers composed of the unsintered grid material are applied and laminated onto one another.

In accordance with a further embodiment, in the method for producing the wavelength conversion element, in a method step B, a plurality of openings are produced in the layer composed of the unsintered ceramic grid material, such that the grid material forms a grid, preferably a yet unsintered grid, in which the openings are surrounded by the ceramic grid material in a main extension plane of the grid and reach through the grid in a direction perpendicular to the main extension plane of the grid. The openings can be introduced into the layer composed of the ceramic grid material by stamping, for example.

In accordance with a further embodiment, in the method for producing the wavelength conversion element in a step C the plurality of openings are filled with conversion segments.

The embodiments and features described above and below apply equally to the wavelength conversion element and to the method for producing the wavelength conversion element.

The grid can form, together with the conversion segments in the openings of the grid, a continuous, large-area wavelength conversion element in which the conversion segments form regions which are separated from one another by the grid and which can convert light, which is irradiated onto the wavelength conversion element, in light, which is different from the incident light. The conversions segments can convert incident light in identical or different light. In particular, it can be advantageous for this purpose if an optical separation of the conversion segments is effected by the grid, such that light which is incident on a certain conversion segment cannot penetrate through the grid into an adjacent conversion segment. Particularly preferably, therefore, the grid can be non-transmissive to ultraviolet and/or visible light. Furthermore, it can be particularly advantageous if the grid is reflective to ultraviolet and/or visible light.

In accordance with a further embodiment, the grid material includes a non-converting ceramic material and is preferably composed of a non-converting ceramic material. In particular, the grid material can include or be composed of one or more undoped ceramic materials selected from yttrium aluminum oxide (YAG), aluminum oxide (Al₂O₃), yttrium oxide (Y₂O₃), titanium oxide (TiO₂) and aluminum nitride (AlN).

The grid material per se can be non-transparent. As an alternative thereto, the grid material per se can also be at least partly transparent. In this case the grid material preferably include an admixture for example in the form of particles or pores, which have the effect that the grid is non-transmissive and preferably reflective to ultraviolet and/or visible light.

In accordance with a further embodiment, the grid material includes radiation-reflecting particles which are arranged in the grid material and which have a different refractive index than the grid material, for example a higher refractive index than the grid material. For instance, the particles can have an optical refractive index of greater than or equal to 1.8. Instead of or in addition to particles, the grid material can also include pores, for example air-filled pores. Pores can be producible for example by additives, for example organic additives, in the unsintered grid material and/or by suitable sintering conditions during the sintering of the grid material.

In accordance with at least one embodiment, the radiation-reflecting particles are formed with at least one of the materials Al₂O₃, SiO₂, TiO₂, ZrO₂ or contain at least one or more of said materials. Additionally or alternatively, one or more of the following materials are also possible: ZnO, BaSO₄, MgO, Ta₂O₅, HfO₂, Gd₂O₃, Nb₂O₃, Y₂O₃. The concentration of the radiation-reflecting particles in the grid material can preferably be greater than or equal to 10% by weight or greater than or equal to 20% by weight. In this case, the radiation-reflecting particles can preferably be distributed uniformly within the grid material.

The grid material and the radiation-reflecting particles and/or the pores can be chosen in such a way that the grid appears white to an observer on account of its reflection properties, since preferably the entire impinging color spectrum of the ambient light is reflected by the grid. As an alternative thereto, it is also possible for the grid to appear differently colored to an observer and to reflect one or more colors. Furthermore, it can also be possible for the grid material to include, for example, non-reflective, in particular absorbent, particles or materials, for example carbon black.

In accordance with a further embodiment, each of the conversion segments includes a wavelength conversion substance. Each of the conversion segments is provided for emitting light by absorbing a primary radiation and re-emitting a secondary radiation, which is different from the primary radiation. For this purpose, the wavelength conversion substance of each conversion element can include or be composed of one or more wavelength conversion substances suitable for absorbing the primary radiation and reemitting secondary radiation.

By way of example, one, a plurality or all of the conversion segments can in each case bring about a full conversion of the primary radiation. That means that the light emitted by a conversion element upon the incidence of primary radiation is substantially formed by the secondary radiation, while no or substantially no primary radiation penetrates through the conversion segment. By way of example, the light emitted by the conversion segment can still have a proportion of the primary radiation of less than or equal to 5% and preferably of less than or equal to 2%. In other words, fully converting conversion segments upon the incidence of primary radiation emit light that is formed by the converted respective secondary radiation and the proportion of the primary radiation of less than or equal to 5% and particularly preferably less than or equal to 2%. Particularly preferably, in the case of a full conversion, the primary radiation in the light respectively emitted by the conversion segments is no longer perceptible by an observer. For this purpose, the conversion segments can have a sufficiently high density of the respective wavelength conversion substance and/or a sufficiently high thickness of greater than or equal to a critical thickness for which the specified full conversion is achieved. In particular, all the conversion segments of the wavelength conversion element can have the same thickness, such that the wavelength conversion element can have a uniform thickness over all the conversion segments.

The wavelength conversion substance of a conversion segment can for example include at least one or more of the following materials for wavelength conversion or be formed from one or more of the following materials: garnets, in particular rare earth doped garnets, sulfides, in particular rare earth doped alkaline earth metal sulfides, rare earth doped thiogallates, rare earth doped aluminates, rare earth doped silicates, for example orthosilicates, rare earth doped chlorosilicates, rare earth doped nitridosilicates, rare earth doped oxynitrides and rare earth doped aluminum oxynitrides, rare earth doped silicon nitrides and rare earth doped oxonitridoalumosilicates, rare earth doped nitridoalumosilicates and aluminum nitrides.

In various embodiments, ceramic materials can be used as wavelength conversion substance, for example garnets such as, for instance, yttrium aluminum oxide (YAG), lutetium aluminum oxide (LuAG), lutetium yttrium aluminum oxide (LuYAG) and terbium aluminum oxide (TAG).

In further preferred embodiments, the ceramic materials for the wavelength conversion substance are doped, for example, with one of the following activators: cerium, europium, neodymium, terbium, erbium, praseodymium, samarium, manganese. Purely by way of example, for possible doped ceramic wavelength conversion substances, mention shall be made of YAG:Ce, LuAG:Ce and LuYAG:Ce. The doped ceramic material can preferably have a content of Ce of greater than or equal to 0.1% and less than or equal to 4%.

Furthermore, the wavelength conversion substance of one, a plurality or all of the conversion segments in further preferred embodiments, can include one or more of the following materials:
(AE)SiON, (AE)SiAlON, (AE)A1SiN₃, (AE)₂Si₅N₈, wherein AE is an alkaline earth metal;
sulfides;
orthosilicates.

The conversion segments can include the wavelength conversion substance in the completed wavelength conversion element as sintered wavelength conversion substance or consist thereof. Furthermore, it can also be possible for the conversion segments to include a wavelength conversion substance for example in powder form in a matrix material. Silicone can particularly preferably be used as matrix material.

In accordance with a further embodiment, one, a plurality or all of the conversion segments can include, in addition to the wavelength conversion substance, even further, in particular inorganic, particles, which preferably have no wavelength-converting properties. Examples of appropriate further particles include nitrides and oxides of the elements aluminum, boron, titanium, zirconium and silicon or mixtures of two or more of the aforementioned materials.

The conversion segments can furthermore include even further elements and constituents in low concentrations.

In accordance with a further embodiment, the wavelength conversion element could include a first opening filled with a first conversion material and a second opening filled with a second conversion material. The first conversion material could be provided for emitting radiation having a first wavelength. The second conversion material could be provided for emitting radiation having a second wavelength. The first and the second wavelength could be different from each other. For instance, the first wavelength could correspond to blue light and the second wavelength could correspond to red light. In addition, the wavelength conversion element could include an third opening filled with a third conversion material, wherein the third conversion material could be provided for emitting radiation having a third wavelength. The third wavelength could correspond to green light. The first and the second conversion material could be arranged in a first and a second opening adjacent to each other. The third opening could be arranged adjacent to the first and the second opening. In addition, the wavelength conversion element could include further openings filled with further conversion materials. According to one specific embodiment, the wavelength conversion element could include three different conversion materials, provided for emitting red light, green light and blue light. According to another specific embodiment, the wavelength conversion element could include four different conversion materials, provided for emitting red light, green light, blue light and white light.

In accordance with a further embodiment, in step C mentioned above, unsintered conversion segments in the form of a slurry or a paste including a ceramic wavelength conversion substance are introduced into the openings of the unsintered ceramic grid material.

In accordance with a further embodiment, in step C unsintered conversion segments in the form of unsintered ceramic platelets are introduced into the openings of the unsintered ceramic grid material. For this purpose, unsintered ceramic platelets can be stamped out from an unsintered ceramic sheet and subsequently be introduced into the openings. It is particularly advantageous if the unsintered ceramic platelets are stamped directly from the unsintered ceramic sheet into the openings.

In accordance with a further embodiment, after step C the unsintered conversion segments are sintered together with the unsintered grid material to form a continuous wavelength conversion element.

If a wavelength conversion substance in a matrix material such as silicone, for example, is used instead of an unsintered ceramic material for the conversion segments, then the unsintered grid material can preferably be sintered before step C. In step C the wavelength conversion substance including the matrix material is then introduced into the openings. The matrix material can subsequently be cured.

In accordance with a further embodiment, a light-emitting semiconductor component includes an above-described wavelength conversion element on a light-emitting semiconductor chip. The light-emitting semiconductor chip can emit primary radiation, for example blue and/or ultraviolet light, via a light coupling-out surface along an emission direction. The wavelength conversion element is applied, for example adhesively bonded, on the light coupling-out surface of the light-emitting semiconductor chip in such a way that the conversion segments are arranged laterally alongside one another on the light coupling-out surface, wherein “laterally” denotes a direction perpendicular to the emission direction.

In accordance with a further embodiment, the light-emitting semiconductor chip has an active region, which can emit light during the operation of the semiconductor chip. The light-emitting semiconductor chip can be produced as a semiconductor layer sequence on the basis of different semiconductor material systems, depending on the desired wavelength to be emitted. For short-wave visible, that is to say in particular blue, primary radiation and/or for ultraviolet primary radiation, a semiconductor layer sequence on the basis of InₓGa_{y}Al_{1-x-y}N is particularly suitable, with 0≦x≦1 and 0≦y≦1.

In particular, the light-emitting semiconductor chip can include or be composed of a semiconductor layer sequence, particularly preferably an epitaxially grown semiconductor layer sequence. For this purpose the semiconductor layer sequence can be grown by means of an epitaxy method, for example metal organic vapor phase epitaxy (MOVPE) or molecular beam epitaxy (MBE), on a growth substrate and can be provided with electrical contacts. A plurality of light-emitting semiconductor chips can be provided by singulating the growth substrate with the grown semiconductor layer sequence.

Furthermore, prior to singulation, the semiconductor layer sequence can be transferred to a carrier substrate and the growth substrate can be thinned or completely removed. Such semiconductor chips including as substrate a carrier substrate instead of the growth substrate can also be designated as so-called thin-film semiconductor chips.

A thin-film semiconductor chip is distinguished, in particular, by the following characteristic features:
a reflective layer is applied or formed at a first main surface—facing toward the carrier substrate—of a radiation-generating epitaxial layer sequence, said reflective layer reflecting at least part of the electromagnetic radiation generated in the epitaxial layer sequence back into the latter;
the epitaxial layer sequence has a thickness in the range of 20 μm or less, in particular in the range of between 4 μm and 10 μm; and
the epitaxial layer sequence contains at least one semiconductor layer having at least one area having an intermixing structure which ideally leads to an approximately ergodic distribution of the light in the epitaxial layer sequence, that is to say it has an as far as possible ergodically stochastic scattering behavior.

A thin-film semiconductor chip is a Lambertian surface emitter to a good approximation. The basic principle of a thin-film light-emitting diode chip is described, for example, in the document I. Schnitzer et al., Appl. Phys. Lett. 63 (16), October 18, 1993, 2174-2176.

In accordance with a further embodiment, the light-emitting semiconductor chip has a plurality of luminous segments which are drivable independently of one another. The luminous segments, which emit the primary radiation via an emission region of the light coupling-out surface in each case during the operation of the light-emitting semiconductor component, can be produced, for example, by a segmentation or structuring of at least one electrical contact area of the semiconductor chip. Furthermore, individual or a plurality of semiconductor layers, for example the active layer, of the semiconductor chip can also be structured. Segmented light-emitting semiconductor chips are known, for example, from the documents WO 2010/072191 and WO 2011/039052, the disclosure content of which in this regard is hereby incorporated by reference.

In accordance with a further embodiment, each conversion segment of the wavelength conversion element is disposed downstream of a luminous segment of the light-emitting semiconductor chip in the emission direction. In particular, a conversion segment of the wavelength conversion element can be disposed downstream of each of the luminous segments of the semiconductor chip, such that each of the luminous segments emits light via its emission region of the light coupling-out surface into the conversion segment respectively disposed downstream. As a result of the segmentation of the light-emitting semiconductor chip and the arrangement of the wavelength conversion element in such a way that the individual conversion segments are in each case disposed downstream of a luminous segment, the light-emitting semiconductor component can emit light with an adjustable color by means of a targeted driving of the individual luminous segments.

If the wavelength conversion element is produced by co-sintering of unsintered conversion segments and the unsintered ceramic grid material, then in a method for producing the light-emitting semiconductor component preferably the wavelength conversion element is completed in accordance with the method described above and is subsequently arranged on the light coupling-out surface of the light-emitting semiconductor chip.

If a matrix material such as silicone, for example, containing the wavelength conversion substance is used for the conversion segments for producing the wavelength conversion element, then preferably in a method for producing the light-emitting semiconductor component, the sintered grid can be arranged on the light coupling-out surface of the light-emitting semiconductor chip before step C, that is to say filling the openings with the conversion segments. Afterward, step C, that is to say filling the openings of the grid with the matrix material and the wavelength conversion substance, can be carried out.

In the case of the wavelength conversion element described here, optical crosstalk between the conversion segments can be prevented by the grid material arranged between the conversion segments. That can be advantageous in particular if each of the conversion segments is assigned to a luminous segment of a light-emitting semiconductor chip. On the basis of the method described here, a large wavelength conversion element, that is to say a wavelength conversion element for example of the size of the light-emitting semiconductor chip, can advantageously be processed without the individual conversion segments having to be individually processed and positioned. As a result, it is possible that an alignment of the individual conversion segments need only be carried out once, namely during an adjustment of the wavelength conversion element, and it is not necessary for each of the conversion segments to be aligned independently of one another. As a result, the conversion segments can have in the main extension plane of the grid a dimensioning that is smaller than 500 μm. Such small conversion segments, if they are present as individual elements, can be positioned only with difficulty. The wavelength conversion element described here makes it possible to avoid difficulties in the case of such small conversion segments in the course of positioning.

### BRIEF DESCRIPTION OF THE DRAWINGS

The invention is explained in greater detail below on the basis of an exemplary embodiment, wherein also as before no distinction will be drawn specifically among the claim categories and the features in the context of the independent claims are intended also to be disclosed in other combinations. In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIGS. 1A to 1D show schematic illustrations of method steps for a method for producing a wavelength conversion element in accordance with one exemplary embodiment,

FIGS. 2 and 3 show schematic illustrations of wavelength conversion elements in accordance with further exemplary embodiments and

FIG. 4 shows a schematic illustration of a light-emitting semiconductor component comprising a wavelength conversion element in accordance with a further exemplary embodiment.

### DETAILED DESCRIPTION

In the exemplary embodiments and figures, elements that are identical, of identical type or act identically may in each case be provided with the same reference signs. The illustrated elements and their size relationships among one another should not be regarded as true to scale; rather, individual elements, such as, for example, layers, component parts, components and regions may be illustrated with an exaggerated size in order to enable better illustration and/or in order to afford a better understanding.

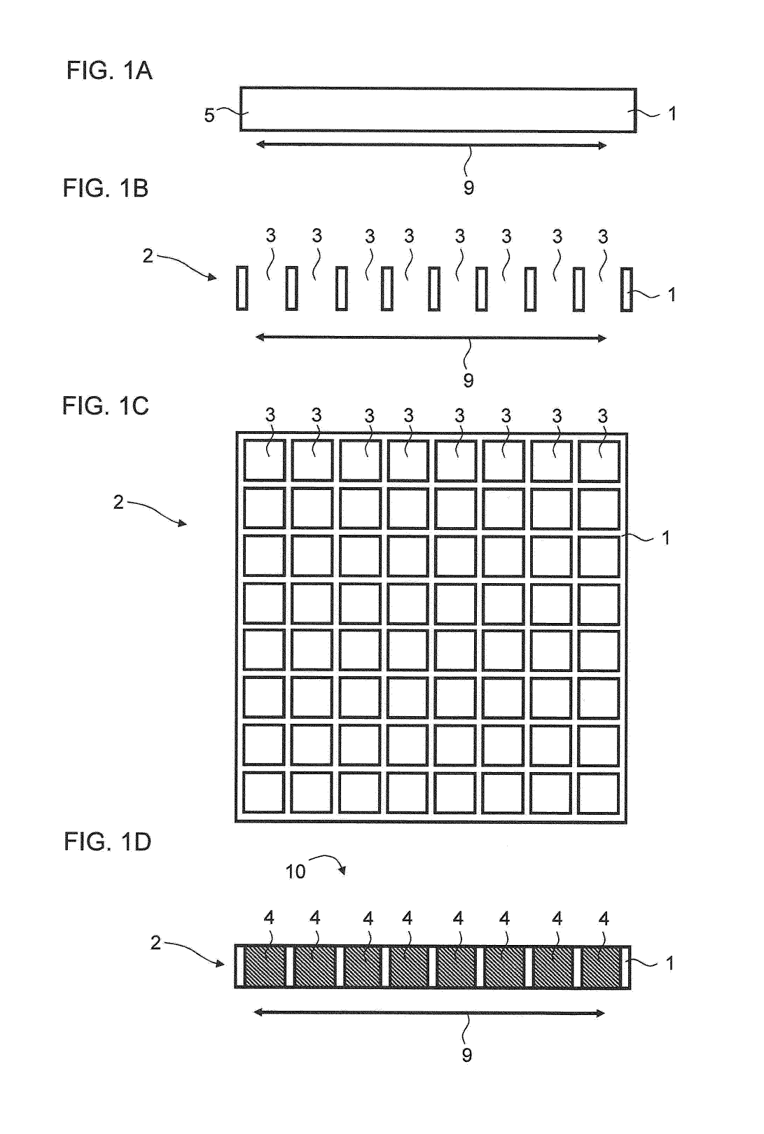

FIGS. 1A to 1D show method steps for producing a wavelength conversion element 10 in accordance with one exemplary embodiment.

In a first method step, as is shown in FIG. 1A, a layer 5 composed of an unsintered ceramic grid material 1 is produced. For this purpose, a slurry or a paste comprising the grid material is produced, and cast to form a tape or green sheet in form of a layer 5. The layer 5 has a main extension plane, indicated by the double-headed arrow 9. The grid material 1 comprises an undoped ceramic material, which is preferably non-converting and which comprises for example one or more of the following materials: YAG, Al₂O₃, Y₂O₃, TiO₂, AlN.

In a further method step in accordance with FIG. 1B, the layer 5 composed of the unsintered ceramic grid material 1 as shown in FIG. 1A is shaped to form a grid 2. For this purpose, a plurality of openings 3 are produced in the layer 5 composed of the grid material 1. The openings 3 can be produced by stamping, for example. The openings 3 are introduced into the grid material 1 along the main extension plane 9 alongside one another in such a way that the openings 3 are surrounded by ceramic grid material 1 in the main extension plane 9 of the grid 2 and project through the grid in a direction perpendicular to the main extension plane 9 of the grid 2.

In addition to the sectional illustration through the grid 2 as shown in FIG. 1B, a plan view of the grid 2 is shown in FIG. 1C. The arrangement of the openings 3 can be matrix-like as shown in FIG. 1C. As an alternative thereto, other geometries of the openings 3 with regard to their form and arrangement are also possible.

In a further method step, as is shown in FIG. 1D, the plurality of openings 3 are filled with conversion segments 4. For this purpose, for example, unsintered conversion segments 4 in the form of a paste or a slurry comprising a ceramic wavelength conversion substance can be introduced into the openings. As an alternative thereto, it is also possible to introduce unsintered conversion segments 4 in the form of unsintered ceramic platelets into the openings. The unsintered ceramic platelets can be stamped out from an unsintered ceramic sheet, for example, wherein it is also possible to stamp the unsintered ceramic platelets directly from the sheet into the openings. After the openings 3 have been filled with the unsintered ceramic conversion segments 4 the latter are co-sintered together with the unsintered grid material 1, as a result of which the wavelength conversion element 10 is completed.

The ceramic wavelength conversion substance of the conversion segments 4 can comprise or be composed of, for example, a doped ceramic material such as, for instance, YAG:Ce, LuAg:Ce or LuYAG:Ce, wherein the content of Ce is preferably greater than or equal to 0.1% and less than or equal to 4%. If such a ceramic material is used as converter material for the conversion segments 4, with regard to the subsequent sintering process in particular a material such as undoped YAG, for example, is advantageous as grid material 1. As an alternative thereto, other combinations of the materials mentioned above in the general part are also possible. By way of example, the conversion segments 4 can also comprise one or more of the following materials: (AE)SiON, (AE)SiAlON, (AE)AlSiN₃, (AE)₂Si₅N₈, wherein AE is an alkaline earth metal; sulfides, orthosilicates.

Instead of filling the openings 3 with an unsintered ceramic material as conversion segments 4, it is also possible to fill the openings 3 with a matrix material, for example silicone, which contains the wavelength conversion substance in powder form, for example. In this case, the grid material 1 is preferably sintered before the openings 3 are filled. With the use of a matrix material such as silicone, with a wavelength conversion substance contained therein, it is possible to use any arbitrary combination of the materials mentioned above in the general part for the wavelength conversion substance and the grid material.

The conversion segments 4 can preferably be designed differently, such that an incident primary radiation is converted into different secondary radiation by the conversion segments 4.

In order to achieve the best possible optical separation of the conversion segments 4, the grid material 1 is preferably non-transmissive to ultraviolet and/or visible light. Particularly preferably, the grid 2 is reflective to ultraviolet and/or visible light. A grid material 1 which per se is non-transparent and preferably reflective can be chosen for this purpose. Furthermore, it is also possible for the grid material 1 to comprise an admixture of particles or pores which have the effect that the grid 2 is non-transmissive and preferably reflective. Pores can be producible for example by means of suitable sintering additives and/or by means of suitable sintering conditions. As radiation-reflecting particles, particles which have a different refractive index than the grid material are preferably added to the grid material 1; by way of example, the particles can comprise or be composed of Al₂O₃, SiO₂, TiO₂, ZrO₂ or some other material mentioned above in the general part. By way of example, a combination of undoped YAG as grid material 1, which is filled with Al₂O₃ or TiO₂ can be particularly advantageous.

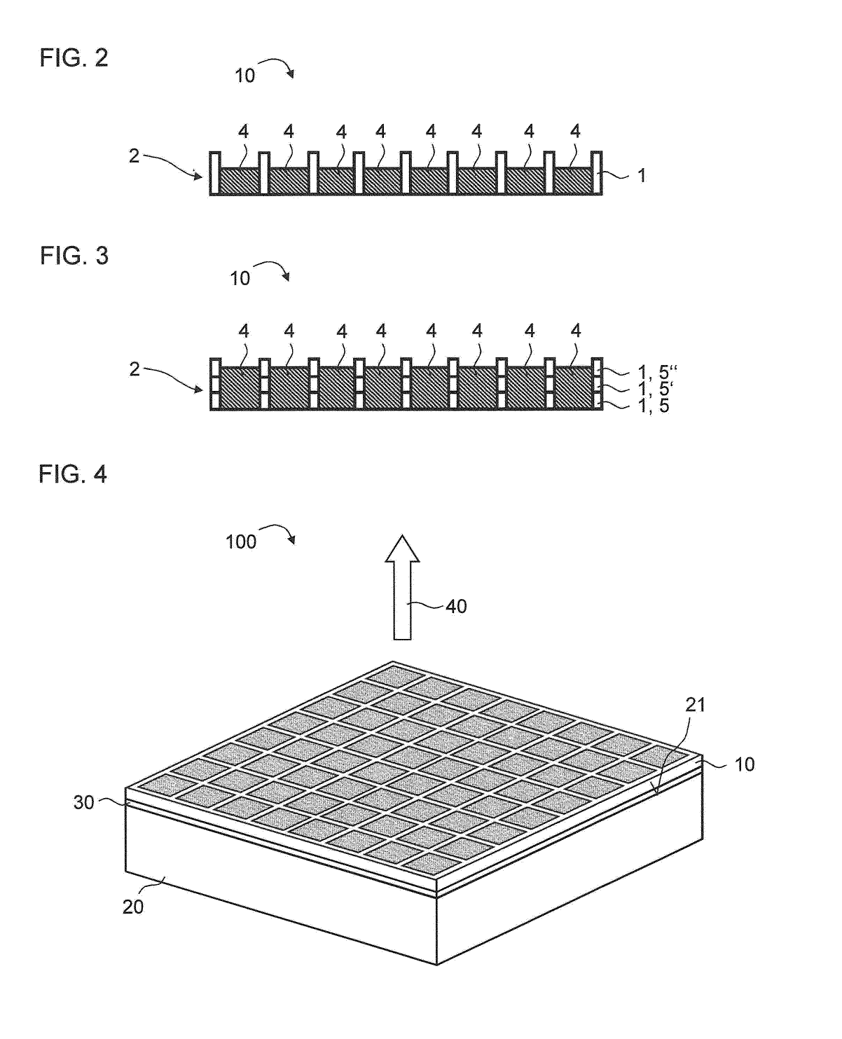

FIG. 2 shows a further exemplary embodiment of a wavelength conversion element 10 wherein, in comparison with the wavelength conversion element 10 of the previous exemplary embodiment, the grid 2 has a larger thickness than the conversion segments 4. An optical separation of the individual conversion segments 4 from one another can be improved as a result.

FIG. 3 shows a further exemplary embodiment of a wavelength conversion element 10, which, in comparison with the exemplary embodiments described previously, comprises, instead of just one layer comprising the ceramic grid material 1, a plurality of sintered layers 5, 5′, 5″ comprising the ceramic grid material 1, which are laminated onto one another in a method step corresponding to that described above in conjunction with FIG. 1A. As a result, it is possible to produce the grid 2 of the wavelength conversion element 10 with a desired height independently of the layer thickness of the grid material 1. Furthermore, it is also possible to use different compositions for the grid material 1 for the individual layers 5, 5′, 5″. The number of three layers 5, 5′, 5″ shown in FIG. 3 is purely by way of example. The grid 2 can have a larger height than the conversion segments 4, as in the exemplary embodiment in FIG. 2. Furthermore, it is also possible for a multilayered grid 2 to have the same thickness as the conversion segments 4.

FIG. 4 shows an exemplary embodiment of a light-emitting semiconductor component 100 comprising a wavelength conversion element 10 in accordance with the previous exemplary embodiments. The wavelength conversion element 10 is arranged on a light-emitting semiconductor chip 20 having a light coupling-out surface 21, via which primary radiation, for example, blue light, can be emitted along the emission direction 40 during the operation. For this purpose, the wavelength conversion element 10 is adhesively bonded by means of a connecting layer 30, for example silicone, on the light coupling-out surface 21 of the semiconductor chip 20.

During the operation of the semiconductor chip 20, the primary radiation of the semiconductor chip 20 is converted into the respective secondary radiation in the conversion segments 4 of the wavelength conversion element 10. The grid 2 between the conversion segments 4, which is preferably non-transmissive to ultraviolet and/or visible light and is particularly preferably designed to be reflective thereto, makes it possible to prevent optical crosstalk between the conversion segments 4. This can be advantageous in particular for the case where the light-emitting semiconductor chip 20 has luminous segments which are drivable independently of one another, each of said luminous segments emitting the primary radiation via an associated emission region of the light coupling-out surface 21 into the conversion segment 4 arranged thereabove, wherein each of the conversion segments 4 of the wavelength conversion element 10 is respectively disposed downstream of one of the luminous segments of the semiconductor chip 20 in the emission direction. By means of an independent and targeted driving of the individual luminous segments of the semiconductor chip 20, the light emitted by the light-emitting semiconductor component 100 can thus be controlled with regard to its intensity and in particular with regard to its color, such that the light-emitting semiconductor 100 enables a variable emission of mixed color and/or white light.

In order to produce the light-emitting semiconductor component 100, the wavelength conversion element 10 can be completed for example before being applied to the semiconductor chip 20, for example by means of joint sintering—described above—of unsintered ceramic conversion segments and the unsintered ceramic grid material.

Furthermore, in particular, with the use of matrix material such as silicone, for instance, filled with a wavelength conversion substance, firstly the sintered grid 2 with unfilled openings 3 should be arranged and fixed on the light coupling-out surface 21 of the light-emitting semiconductor chip 20 and the matrix material comprising the wavelength conversion substance for producing the conversion segments 4 should subsequently be filled into the openings 3 of the grid.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A wavelength conversion element comprising a ceramic grid material, which forms a grid having a plurality of openings, which are surrounded by the grid material in a main extension plane of the grid and reach through the grid in a direction perpendicular to the main extension plane of the grid, wherein the openings are filled with conversion segments.

2. The wavelength conversion element according to claim 1, wherein the grid is non-transmissive to ultraviolet and/or visible light.

3. The wavelength conversion element according to claim 1, wherein the grid is reflective to ultraviolet and/or visible light.

4. The wavelength conversion element according to claim 1, wherein the grid material comprises an undoped ceramic material selected from one or more of the following materials: YAG, Al₂O₃, Y₂O₃, TiO₂, AlN.

5. The wavelength conversion element according to claim 1, wherein pores or radiation-reflecting particles having a different refractive index than the grid material are arranged in the grid material.

6. The wavelength conversion element according to claim 5, wherein the radiation-reflecting particles comprise at least one or more of the following materials: Al₂O₃, SiO₂, TiO₂, ZrO₂.

7. The wavelength conversion element according to claim 1, wherein the grid has a thickness which is greater than a thickness of the conversion segments.

8. The wavelength conversion element according to claim 1, wherein the conversion segments comprise a doped ceramic material selected from one or more of the following materials: YAG:Ce, LuAG:Ce, LuYAG:Ce.

9. The wavelength conversion element according to claim 8, wherein the doped ceramic material has a content of Ce of greater than or equal to 0.1% and less than or equal to 4%.

10. The wavelength conversion element according to claim 1, wherein the conversion segments comprise one or more materials selected from the following:
(AE)SiON, (AE)SiAlON, (AE)AlSiN₃, (AE)₂Si₅N₈, wherein AE is an alkaline earth metal;
sulfides;
orthosilicates.

11. The wavelength conversion element according to claim 1, wherein the conversion segments comprise a wavelength conversion substance in a matrix material.

12. The wavelength conversion element according to claim 1, wherein a first opening is filled with a first conversion material and a second opening is filled with a second conversion material, wherein the first conversion material is provided for emitting radiation having a first wavelength and the second conversion material is provided for emitting radiation having a second wavelength, and wherein the second wavelength is different from the first wavelength.

13. A method for producing a wavelength conversion element, the method comprising:
A) producing a layer composed of an unsintered ceramic grid material,
B) producing a plurality of openings in the layer, such that the grid material forms a grid, in which the openings are surrounded by the ceramic grid material in a main extension plane of the grid and reach through the grid in a direction perpendicular to the main extension plane of the grid, and
C) filling the openings with conversion segments.

14. The method according to claim 13, wherein a plurality of layers composed of the unsintered grid material are applied one on top of another in order to form the grid.

15. The method according to claim 13,
wherein in C unsintered conversion segments in the form of a paste comprising a ceramic wavelength conversion substance are introduced into the openings, or
wherein in C unsintered conversion segments in the form of unsintered ceramic platelets are introduced into the openings.

16. The method according to claim 13, wherein after C the unsintered conversion segments are sintered together with the unsintered grid material in order to form a continuous wavelength conversion element.

17. The method according to claim 13, wherein the unsintered grid material is sintered before C, and in C a wavelength conversion substance in a matrix material is introduced into the openings.

18. A light-emitting semiconductor component comprising a light-emitting semiconductor chip, which during operation emits a primary radiation via a light coupling-out surface along an emission direction, and a wavelength conversion element,
the wavelength conversion element comprising
a ceramic grid material, which forms a grid having a plurality of openings, which are surrounded by the grid material in a main extension plane of the grid and reach through the grid in a direction perpendicular to the main extension plane of the grid, wherein the openings are filled with conversion segments,
wherein the conversion segments are arranged laterally alongside one another on the light coupling-out surface.

19. (canceled)
